(19) United States
(12) Patent Application Publication
(10) Pub. No.: US 2008/0239227 A1
(43) Pub. Date: Oct. 2, 2008

(54) Pixel Structure, Display Panel, Electro-Optical Device, and Method for Manufacturing the Same

(75) Inventors: Shih-Chyuan Fan Jiang, Hsin-Chu (TW); Ching-Huan Lin, Hsin-Chu (TW); Chih-Ming Chang, Hsin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORPORATION, Hsin-Chu (TW)

(21) Appl. No.: 11/865,994

(22) Filed: Oct. 2, 2007

(30) Foreign Application Priority Data
Mar. 27, 2007 (TW) 96110594

(51) Int. Cl. G02F 1/1343; H01L 21/02

(52) U.S. Cl. 349/144; 438/30; 257/E21.536

(57) ABSTRACT

A pixel structure has a pair of substrates, a liquid crystal layer, pixel regions, a patterned organic material layer, and a shielding layer. The liquid crystal layer is disposed between the pair of substrates. The pixel regions are provided on the substrates, and each of the pixel regions is defined by at least two common lines and at least one data line and includes at least two sub-pixel regions. Each pixel region has a pixel electrode which has a main slit adjacent to the border between the two sub-pixel regions. The patterned organic material layer is disposed on one of the substrates and corresponds to one of the sub-pixel regions. The shielding layer is placed corresponding to the main slit. Display panel and electro-optical device which have the pixel structure and the methods for manufacturing them are also disclosed.

### RELATED APPLICATIONS

This application claims the benefit of priority based on Taiwan Application Number 96110594, filed Mar. 27, 2007, the contents of which are incorporated herein by reference in their entirety.

### BACKGROUND OF THE INVENTION

1. Field of Invention

The present invention relates to a liquid crystal display and, most particularly, to a pixel structure and a method for manufacturing the same.

2. Related Art

FIG. 1A is a top view of the conventional transflective multi-domain vertical alignment (MVA) pixel structure. The transflective MVA pixel structure 100 uses two common lines 122 and two data lines 124 to define a pixel region 110. Each pixel region 110 contains two sub-pixel regions. One of them is a reflective region 112, and the other is a transparent region 114. The reflective region 112 and the transparent region 114 are electrically connected via electrodes 151.

FIG. 1B is a cross-sectional view of FIG. 1A along the AA′ line. The pixel structure 100 includes a pair of glass substrates 130, 140, with a liquid crystal layer 150 disposed in between. The glass substrate 130 is disposed in sequence a color filter layer 132 and an overcoat layer 134. The reflective region 112 has a patterned organic material layer 164 disposed on the overcoat layer 134. A common electrode 136 covers the overcoat layer 134 in the transparent region 114 and the patterned organic material layer 164 in the reflective region 112. The common electrode 136 is made of ITO. Protrusions 162, 166 are formed on the common electrode 136, corresponding to black matrices 172, 176.

A polysilicon layer 141, an insulating layer 142, a first metal layer (M1) 143, an insulating layer 144, a second metal layer (M2) 145, a passivation layer 146, and pixel electrodes 148, 149 are formed in sequence on the glass substrate 140. They are respectively patterned to form a thin-film transistor 128, a storage capacitor 129, a common line 122, a scan line 126, a contact hole 182, and a via hole 184. The material of the passivation layer 146 is silicon nitride. The material of the pixel electrode 148 in the transparent region 114 is ITO. The material of the pixel electrode 149 in the reflective region 112 is reflective. It is thus also called a reflective layer. It is disposed on the passivation layer 146 corresponding to the patterned organic material layer 164 for reflecting the light from the environment in the reflective region 112.

This pixel structure 100 is provided protrusions 162, 166 in the reflective region 112 and the transparent region 114 for changing the electricity line distribution when there is a potential difference between the common electrode 136 of the pixel structure 100 and the pixel electrodes 148, 149. In that case, the liquid crystal molecules in the liquid crystal layer 150 tilt toward the direction of the protrusions 162, 166. This achieves a wide viewing angle by having multiple regions, and solves the grey level inversion problem existing in the single-region pixel structure. Moreover, the pixel structure 100 usually has dual gaps. That is, the reflective region 112 is disposed with a patterned organic material layer 164 for adjusting the optical path difference. The purpose is to have approximately the same optical path for the reflected and transmitted light, reaching the optimized optical performance for the transmitted and reflective light.

As shown in FIG. 2, the liquid crystal molecules 152 at the boundary of the patterned organic material layer 164 may be affected by the border of it and cannot have ideally vertical alignment. In this case, the border of the patterned organic material layer 164 has light leakage at dark state, thus lowering the transmissive contrast of the conventional pixel structure 100.

### SUMMARY OF THE INVENTION

The present invention is provided to a pixel structure that prevents the pixel structure from producing light leakage at dark state and increases its transmissive contrast. The present invention also discloses a method for manufacturing the same.

The present invention provides a pixel structure includes a pair of substrates, a liquid crystal layer, several pixel regions, a patterned organic material layer, and a shielding layer. The liquid crystal layer is disposed between the pair of substrates. The pixel regions are provided on the substrates, and each of the pixel regions is defined by at least two common lines and at least one data line and includes at least two sub-pixel regions. Each pixel region has a pixel electrode which has a main slit substantially adjacent to the border between the two sub-pixel regions. The patterned organic material layer is disposed on one of the substrates and substantially aligns with one of the sub-pixel regions. The shielding layer is substantially aligned with the main slit.

The present invention provides a method for manufacturing the pixel structure disclosed herein includes: providing a pair of substrates; forming a plurality of pixel regions on the substrates, each of the pixel regions is defined by at least two common lines and at least one data line and has at least two sub-pixel regions; forming a pixel electrode containing at least one main slit in each of the pixel regions, wherein the main slit is substantially adjacent to the border between the two sub-pixel regions; disposing a patterned organic material layer on one of the substrates, substantially aligned with one of the sub-pixel regions; and forming a shielding layer substantially aligned with the main slit.

The present invention further provides to a display panel incorporating the above-mentioned pixel structure and the method for manufacturing the same.

The present invention further provides to an electro-optical device incorporating the above-mentioned display panel and the method for manufacturing the same.

### BRIEF DESCRIPTION OF THE DRAWINGS

These and other features, aspects and advantages of the present invention will become apparent by reference to the following description and accompanying drawings which are given by way of illustration only, and thus are not limitative of the present invention, and wherein:

FIG. 1A is a top view of the conventional transflective multi-domain vertical alignment (MVA) pixel structure;

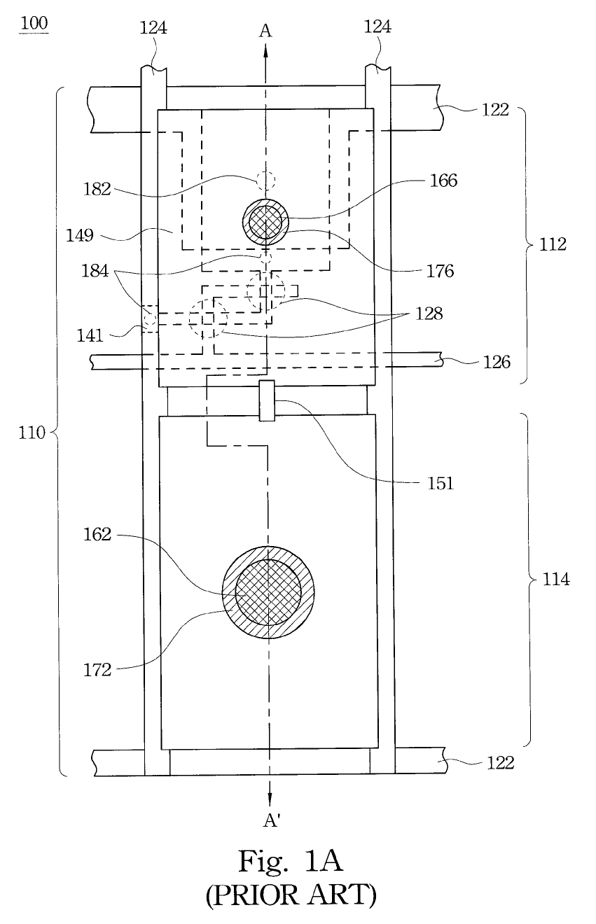

FIG. 1B is a cross-sectional view of FIG. 1A along the AA′ line;

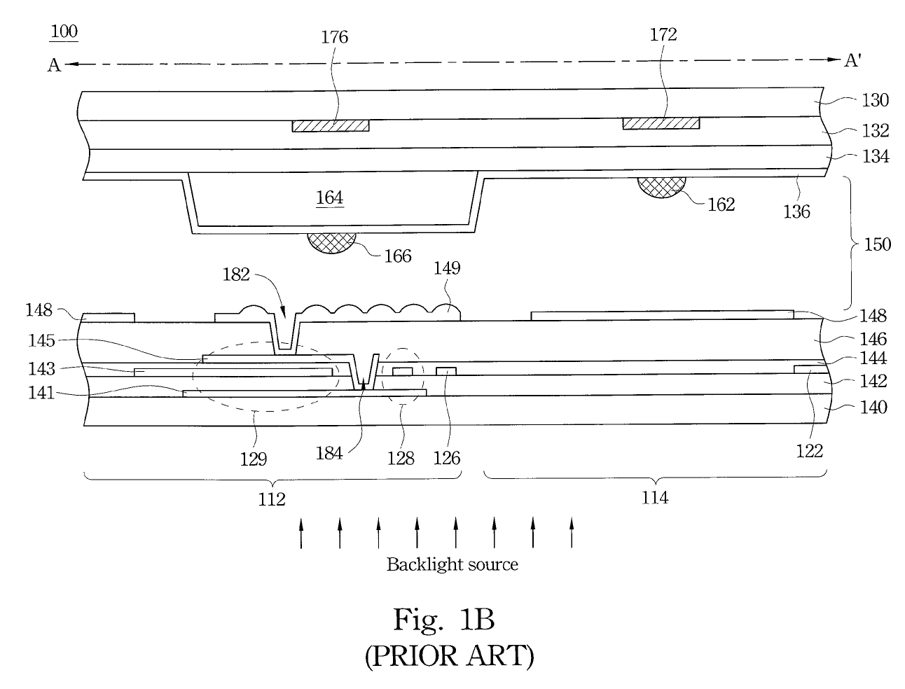

FIG. 2 is a cross-sectional view showing the alignment of liquid crystal molecules when the potential difference between the pixel electrode and the common electrode of the pixel structure in FIG. 1A is approximately zero (i.e., the dark state);

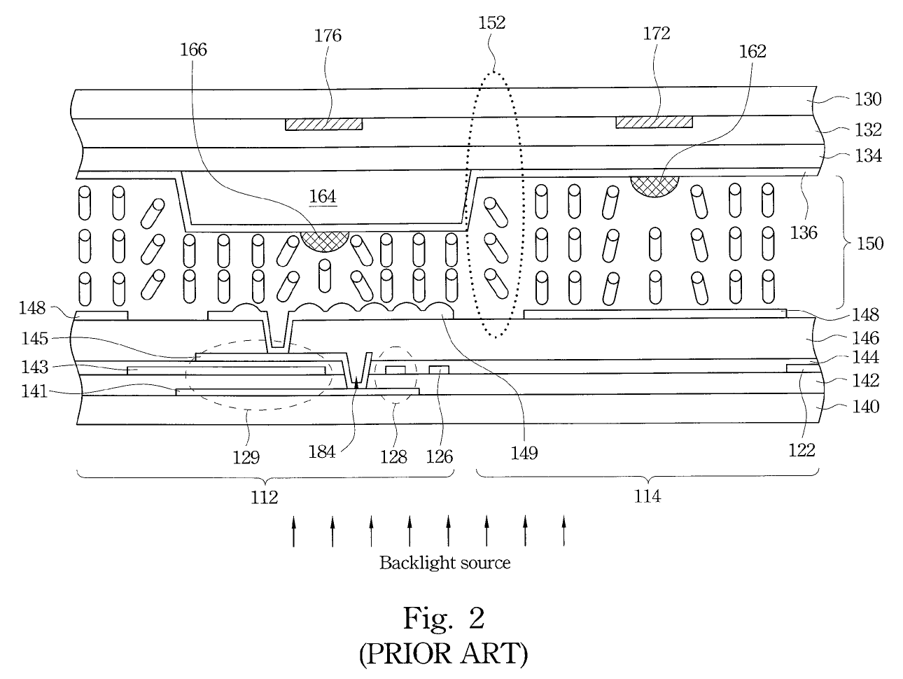

FIG. 3 is a top view of the pixel structure according to the first embodiment of the present invention;

FIG. 4A is a cross-sectional view of a first variation of the pixel structure in FIG. 3 along the AA′ line;

FIG. 4B is a cross-sectional view of a second variation of the pixel structure in FIG. 3 along the AA′ line;

FIG. 4C is a cross-sectional view of a third variation of the pixel structure in FIG. 3 along the AA′ line;

FIG. 5 is a flowchart of the manufacturing method according to a first embodiment of the present invention;

FIG. 6 is a top view of the alignment of liquid crystal molecules in the liquid crystal layer when a potential difference exists between the pixel electrode and the common electrode of the pixel structure in FIG. 3;

FIG. 7A is a cross-sectional view of the alignment of liquid crystal molecules when a potential difference exists between the pixel electrode and the common electrode of the pixel structure in FIG. 4A (i.e., the bright state);

FIG. 7B is a cross-sectional view of the alignment of liquid crystal molecules when the potential difference between the pixel electrode and the common electrode of the pixel structure in FIG. 4A is approximately zero (i.e., the dark state);

FIG. 8 is a top view of the pixel structure according to the second embodiment of the present invention;

FIG. 9 is a top view of the pixel structure according to the third embodiment of the present invention;

FIG. 10A is a cross-sectional view of a first variation of the pixel structure in FIG. 9 along the AA′ line;

FIG. 10B is a cross-sectional view of a second variation of the pixel structure in FIG. 9 along the AA′ line;

FIG. 10C is a cross-sectional view of a third variation of the pixel structure in FIG. 9 along the AA′ line;

FIG. 11 is a cross-sectional view of the pixel structure according to the fourth embodiment of the present invention;

FIG. 12 is a cross-sectional view of the pixel structure according to the fifth embodiment of the present invention; and

FIG. 13 is a schematic view of the electro-optical device in the seventh embodiment of the present invention.

### DETAILED DESCRIPTION OF THE INVENTION

The present invention will be apparent from the following detailed description, which proceeds with reference to the accompanying drawings, wherein the same references relate to the same elements.

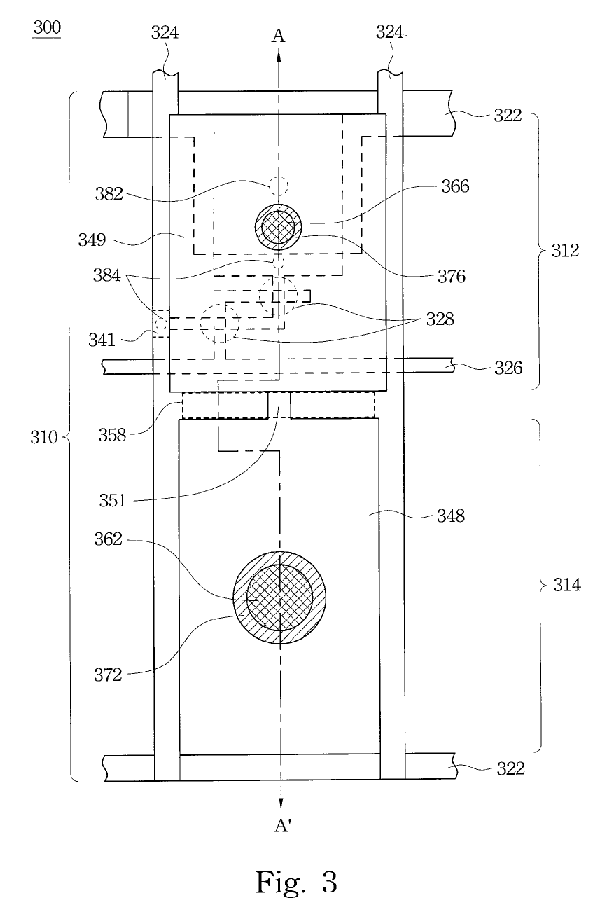

As shown in FIG. 3, the pixel structure 300 according to a first embodiment of the present invention includes a pixel region 310 defined by at least two common lines 322 and at least one data line 324. The pixel region 310 has at least two sub-pixel regions. In the following embodiment, one sub-pixel region is a reflective region 312, and the other is a transparent region 314. This configuration is merely an example for the illustration purpose. The present invention is not limited to this implementation. For example, the sub-pixel regions in a pixel region can be all transparent or reflective.

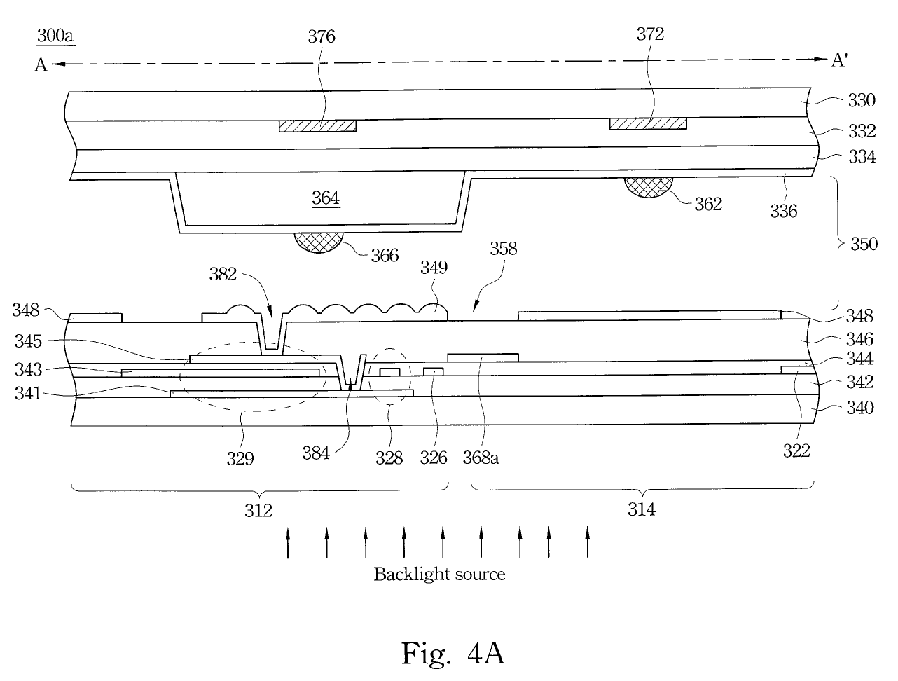

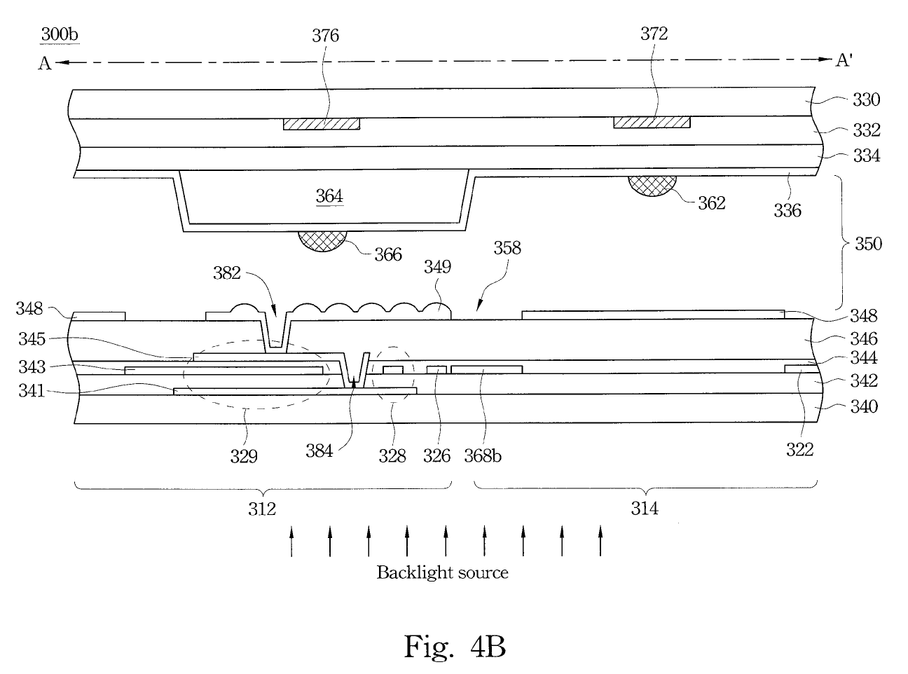

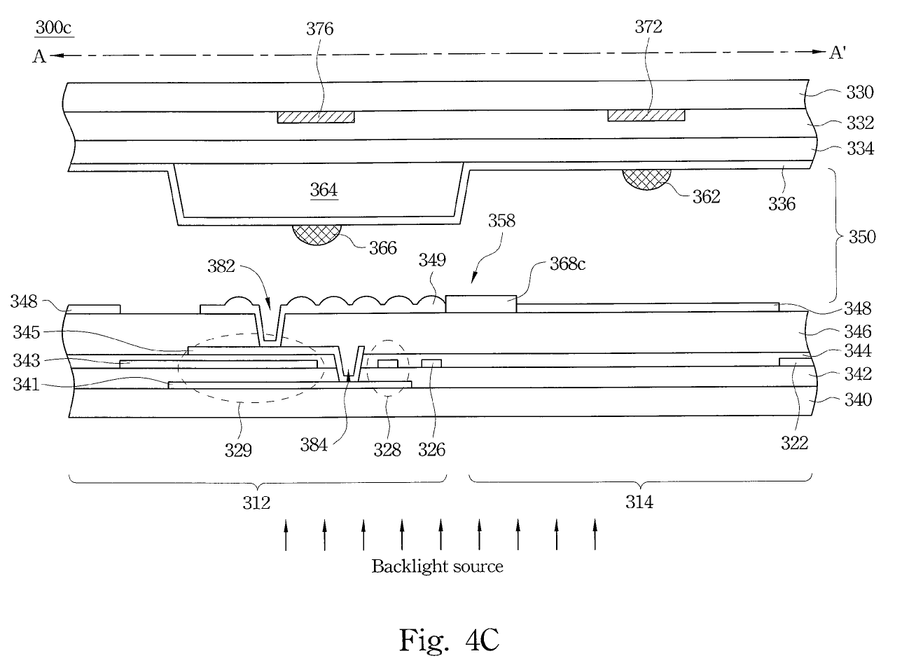

The reflective region 312 and the transparent region 314 are electrically connected via a connecting electrode 351. The pixel region 310 includes a pixel electrode (not shown) containing a main slit 358. The main slit 358 is between the reflective region 312 and the transparent region 314. In the first embodiment, the shielding layer, such as a metal layer 368a (shown in FIG. 4A), a metal layer 368b (shown in FIG. 4B), a non-transparent insulating layer 368c (such as a non-transparent insulating layer, shown in FIG. 4C), or some combination of them, is placed corresponding to the main slit 358. This reduces the light leakage of the pixel structure 300 at dark state. Several variations of the pixel structure 300 in FIG. 3 are shown in the cross-sectional plots in FIGS. 4A˜4C.

FIG. 4A show the pixel structure 300a along the AA′ line in FIG. 3. The pixel structure 300a includes a pair of substrates 330, 340. A liquid crystal layer 350 with a plurality of liquid crystal molecules is disposed between the substrates 330, 340. The material of at least one of the substrates 330, 340 comprises a transparent material (e.g., glass, quartz, etc), non-transparent material (e.g., silicon plate, ceramics, etc), flexible material (e.g., polyester, polyethylene, polyamide, polyethanol, polycyclane, polyphenol, thinner glass, others, or combination of them). The substrates 330, 340 in the first embodiment are glass substrate as an example.

The substrate 330 is provided by a color filter layer 332 and an overcoat later 334 covering the color filter layer 332. The reflective region 312 has a patterned organic material layer 364 disposed on the overcoat layer 334. The patterned organic material layer 364 of the reflective region 312 renders an optical path for the reflected light in reflective region that is substantially equal to an optical path for transmitted light in the transparent region, in order to optimize the performance of transmissive optics and reflective optics. The common electrode 336 covers the overcoat layer 334 of the transmissive region 314 and the patterned organic material layer 364 of the reflective region 312. The common electrode 336 is made of a transparent conductive material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combinations thereof. Alignment elements 362, 366 are formed on the common electrode 336. Black matrices 372, 376 are disposed on and aligned with the alignment elements 362, 366.

A semiconductor layer 341, an insulating layer 342, a first metal layer (M1) 343, an insulating layer 344, a second metal layer (M2) 345, a passivation layer 346, and pixel electrodes 348, 349 are formed in sequence on the substrate 340. They are respectively patterned to form a thin-film transistor 328, a storage capacitor 329, a common line 322, a scan line 326, a contact hole 382, and a via hole 384.

At least one of materials of the insulating layer 342, insulating layer 344, overcoat layer 334, and passivation layer 346 comprises an organic material [e.g., photo resist, polyarylene ether (PAE), polyester, polyethylene, polyamide, polyethanol, benzocyclclobutene (BCB), hydrogen silsesquioxane (HSQ), methyl silesquioxane (MSQ), SiOC—H, or some other material or a combination of the above], an inorganic material (e.g., silicon oxides, silicon nitrides, silicon oxy-nitride, silicon carbonates, hafnium oxides, or some other material or a combination of the above), or any combinations thereof. The pixel electrode 348 in the transparent region 314 is made of a transparent conducting material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combination thereof.

The semiconductor layer 341 comprises a polycrystal material containing Si, microcrystal material containing Si, single crystal material containing Si, amorphous material containing Si, or any combinations thereof. The pixel electrode 349 in the reflective region 312 is made of a reflective material. It is also called a reflective layer. It is disposed on the passivation layer 346 corresponding to the patterned organic material layer 364 adapted to reflect light of the environment in the reflective region 312. The pixel electrode 349 employs a rough and uneven surface of the passivation layer 346, and then is coated with a metal layer with high reflectivity (e.g., Al, Au, Ag, Cr, Mo, Nb, Ti, Ta, W, Nd, their alloys, other material, or a combination of the above) on the surface with rough and uneven of the passivation layer 346 to form the rough and uneven surface of the pixel electrode, a reflective metal layer with a rough and uneven surface formed on the surface without roughness and unevenness of the passivation layer 346, or combinations thereof.

The shielding layer can be a non-transparent metal layer, a non-transparent insulating layer, or combinations thereof. The first variation example of FIG. 4A employs the non-transparent metal layer 368a in the second metal layer 345 as the shielding layer of the pixel structure 300a. The metal layer 368a can be selectively connected with or non-connected with the data line 324, and the data line 324 is made from the second metal layer 345, for example. That is, the metal layer 368a functioning as a shielding layer can be connected to a specific potential or be floating without connecting to any potential , such as the scan line, data line, common line, or other signal source line.

FIG. 4B is the cross-sectional view of the second variation of the pixel structure 300 in FIG. 3. The pixel structure 300b is drawn along the AA′ line in FIG. 3. The second variation example in FIG. 4B employs the non-transparent metal layer 368b in the first metal layer 343 as the shielding layer of the pixel structure 300b. Moreover, the metal layer 368b is preferably floating instead of connecting to any particular potential. It can also be connected with the scan line 326 on the first metal layer 343 to have a specific potential, and the scan line 326 is made from the first metal layer 343, for example.

In FIG. 4C, the pixel structure 300c is drawn along the AA′ line in FIG. 3. The third variation example in FIG. 4C employs the non-transparent insulating layer 368c as the shielding layer of the pixel structure 300c. The material of the non-transparent insulating layer 368c is preferably a photo resist, some other organic material (in the color of, for example, black, light color, multiple colors covered with each other, or some other color), an inorganic material, or any combinations thereof. It can be selectively formed on at least one of the substrate 340, the insulating layer 342, the insulating layer 344, and the passivation layer 346. For example, it can be disposed at the main slit 358 in FIG. 4C, as well as the positions illustrated in FIGS. 4A˜4C or some other position. The shielding layer in the first embodiment can be implemented by selectively using at least two schemes in FIGS. 4A˜4C.

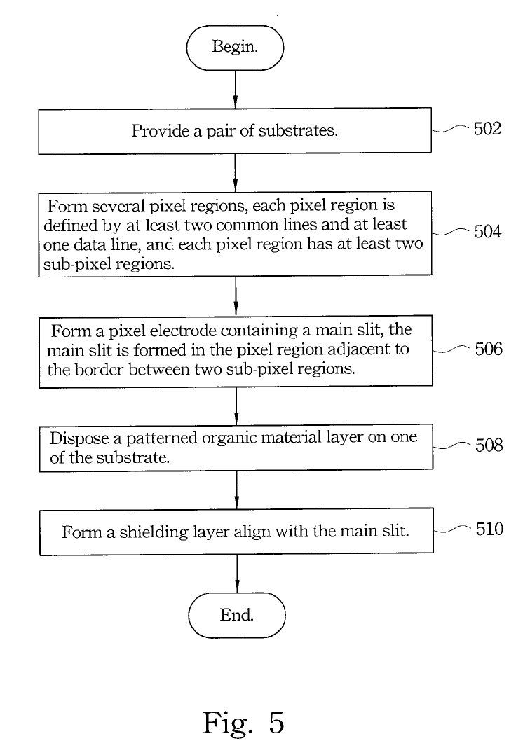

Please refer simultaneously to FIGS. 3, 4A˜4C for the description of the disclosed method given in FIG. 5. This method provides a pair of substrates 330, 340 (step 502). In step 504, several pixel regions 310 are formed on the substrates 330, 340. Each pixel region 310, is defined by at least two common lines 322 and at least one data line 324, and has at least two sub-pixel regions, such as the reflective region 312 and the transparent region 314. However, the present invention is not limited to this example. They can both be reflective regions or transparent regions. In step 506, pixel electrodes 348, 349 containing at least one main slit 358 are formed in the pixel region 310 substantially adjacent to the border between the two sub-pixel regions 312, 314. In step 508, a patterned organic material layer 364 is disposed on one of the substrates 330, 340, substantially aligning with one of the sub-pixel regions 312, 314. In step 510, a shielding layer, such as a metal layer 368a, a metal layer 368b, an non-transparent insulating layer, or a combination of the above, is formed substantially aligning with the main slit 358.

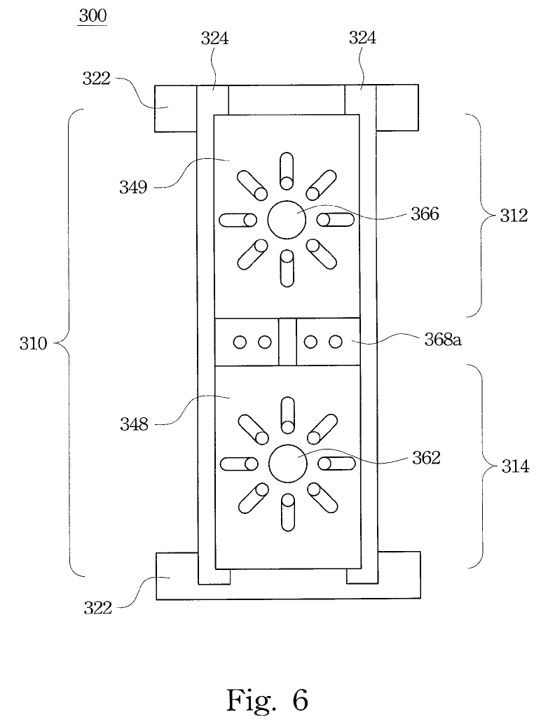

FIG. 6 is a top view showing the alignment of the liquid crystal molecules in the liquid crystal layer when a potential difference exists between the pixel electrodes 348, 349 and the common electrode 336 for the pixel structure 300 in FIG. 3. According to the first embodiment, when a potential difference exists between the pixel electrodes and the common electrode of the pixel structure 300, the liquid crystal molecules at the border of the reflection region 312 and the transparent region 314 are aligned well regardless whether there is a potential on the shielding layer. That is, when the pixel structure is driven at the bright state by the potential difference between the pixel electrodes and the common electrode, whether the metal layer is used as the shielding layer and whether it has a potential do not affect the normal performance of the pixel structure at the bright state. Therefore, it can effectively improve the liquid crystal molecules of the traditional pixel structure in the boundary of the patterned organic material layer.

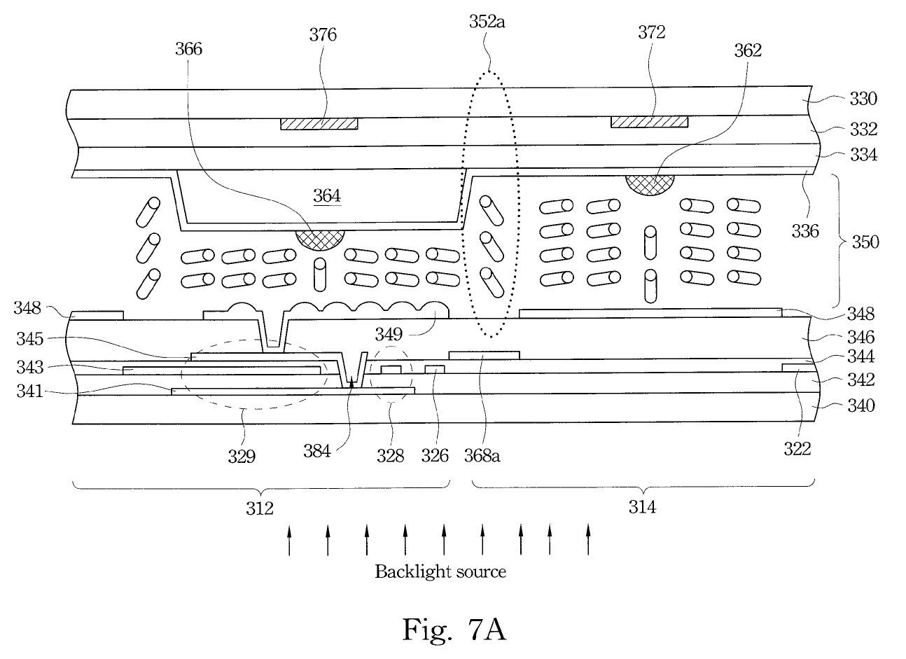

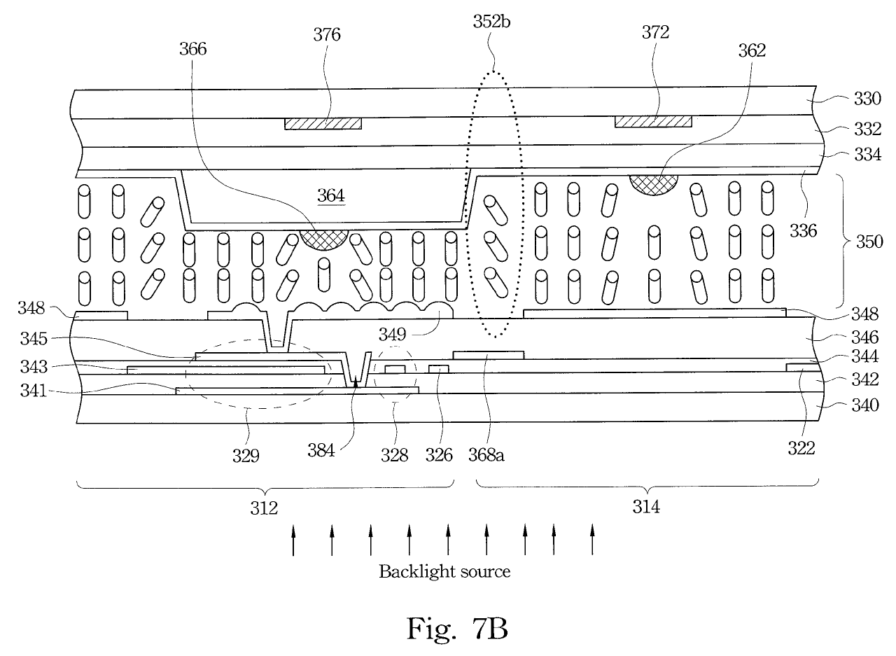

FIG. 7A is a cross-sectional view showing the alignment of the liquid crystal molecules 352a when a potential difference exists between the pixel electrodes 348, 349 and the common electrode 336 (i.e., in the bright state) for the pixel structure 300a in FIG. 4A. FIG. 7B is a cross-sectional view showing the alignment of the liquid crystal molecules 352b when the potential difference between the pixel electrodes 348, 349 and the common electrode 336 is approximately zero (i.e., in the dark state) for the pixel structure 300a in FIG. 4A. The metal layer 368a in FIGS. 7A and 7B is connected with the data line 324, so that the metal layer 368a as the shielding layer and the data line have the same potential. According to FIG. 7B, when the liquid crystal molecules 352b at the boundary of the patterned organic material layer 364 cannot have perfectly perpendicular alignment due to the topology, the pixel structure 300a can block the light using the metal layer 368a (or the metal layer 368b in FIG. 4B, the non-transparent insulating layer 368c in FIG. 4C, or combinations thereof). This prevents the light leakage at dark state, as well as enhances the penetrating contrast of the pixel structure.

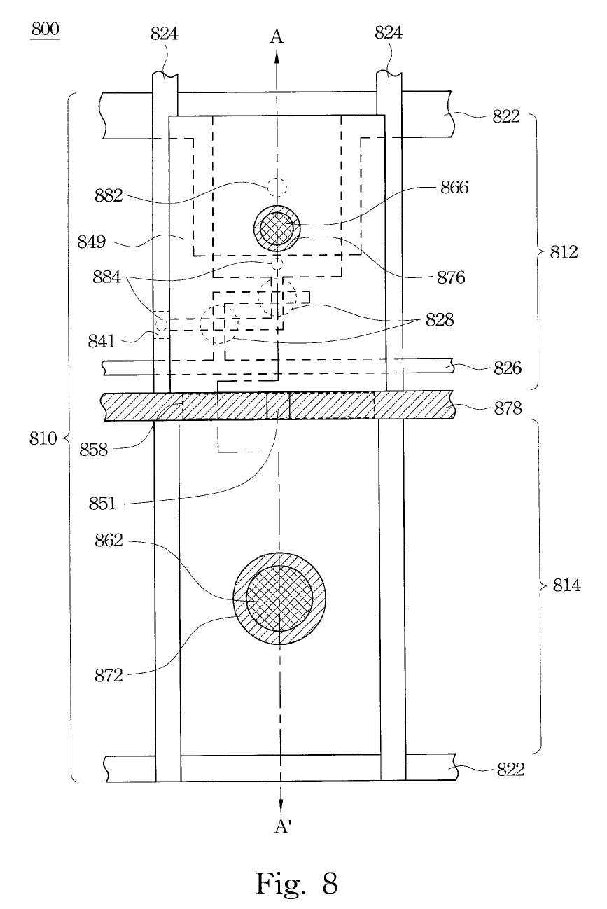

FIG. 8 is a top view of a pixel structure according to a second embodiment of the present invention. The pixel structure 800 uses at least two common lines 822 and at least one data line 824 to define a pixel region 810. Each pixel region 810 includes at least two sub-pixel regions. In the following example, one sub-pixel region functions as a reflective region 812 and the other functions as a transparent region 814. However, the present invention is not limited to this case. The sub-pixel regions in each pixel region can be all be transparent regions or reflective regions.

The reflective region 812 and the transparent region 814 are electrically coupled by connecting with the electrode 851. The reflective region 812 has a thin-film transistor 828, a contact hole 882, and a via hole 884. The pixel region 810 has a pixel electrode (not shown) having a main slit 858. The main slit 858 is formed between the reflective region 812 and the transparent region 814.

In the second embodiment, in addition to disposing a shielding layer (e.g., a metal layer 868 as in the first embodiment) substantially aligning with the main slit 858 in the pixel structure 800, a black matrix 878 can be disposed corresponding to or substantially aligned with the shielding layer to further reduce the light leakage at the dark state. The black matrix 878 can be selectively disposed on at least one of the substrates. In this embodiment, the black matrix 878 is disposed on the substrate without the thin-film transistor. The present invention, however, is not restricted by this example. The black matrix 878 can be disposed on the substrate with the thin-film transistor as well. Besides, the shielding layer here can be the above-mentioned non-transparent metal layer on the first metal layer, the non-transparent metal layer on the second metal layer, the non-transparent insulating layer, or combinations thereof. That is, any person skilled in the art can select an individual or combination of the above-mentioned shielding layer embodiments and the corresponding black matrix to achieve the purpose of reducing the light leakage at dark state of the pixel structure.

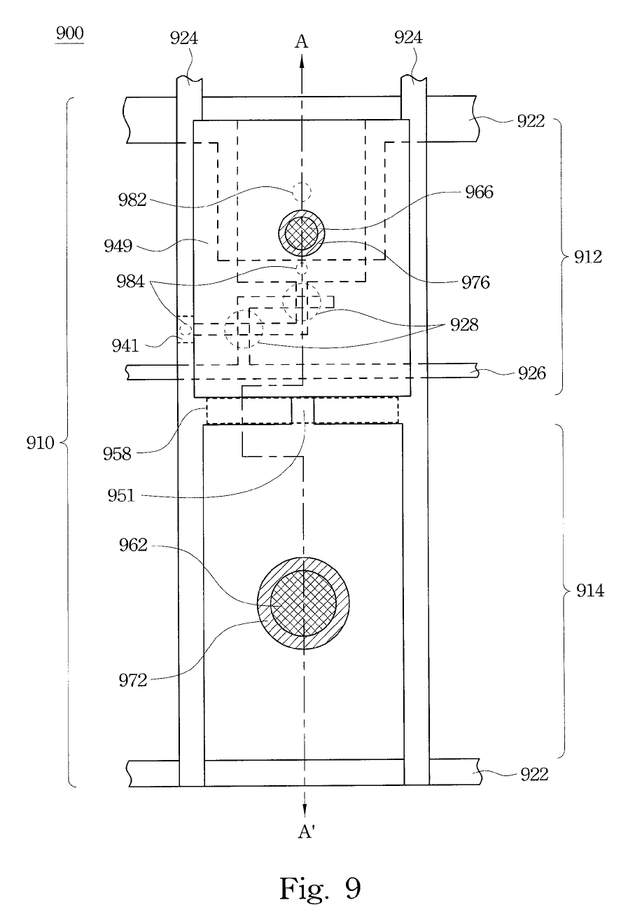

FIG. 9 is a top view of the pixel structure in a third embodiment of the present invention. The pixel structure 900 uses at least two common lines 922 and at least one data line 924 to define a pixel region 910. The pixel region 910 includes at least two sub-pixel regions. In the following embodiment, one sub-pixel region functions as a reflective region 912 and the other functions as a transparent region 914. However, the present invention is not limited to this case. The sub-pixel regions in each pixel region can be all be transparent regions or reflective regions.

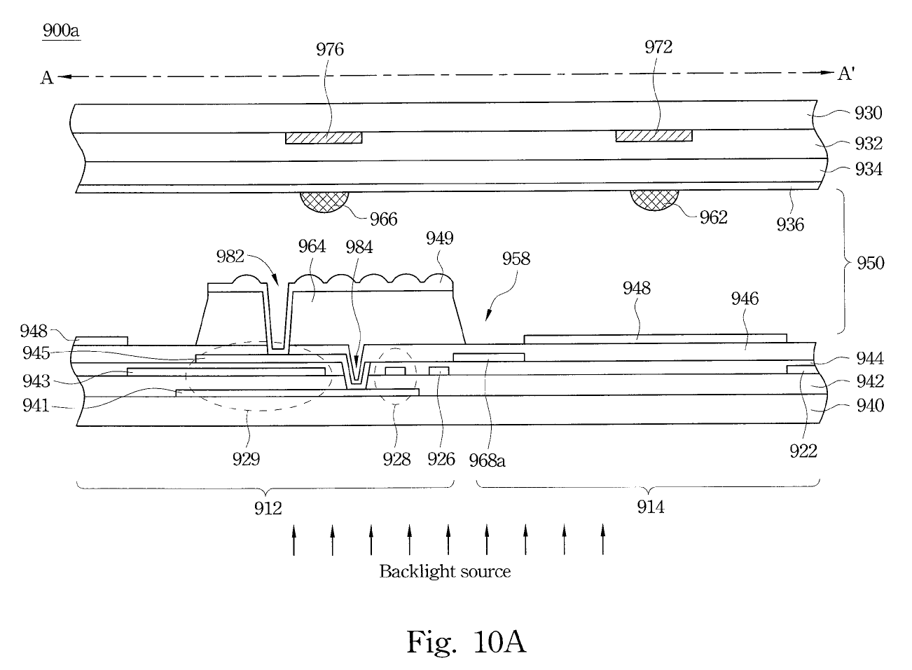

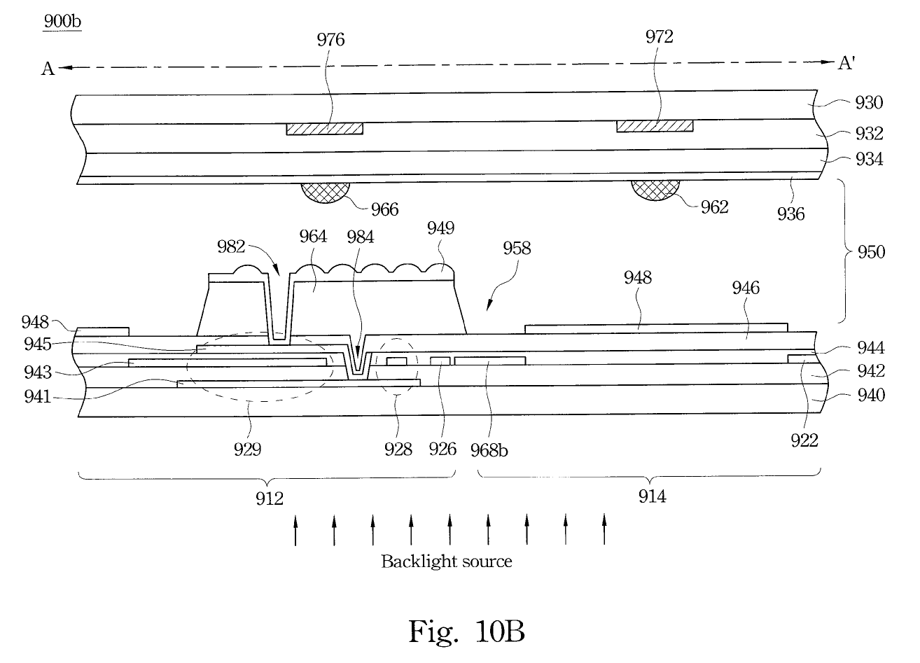

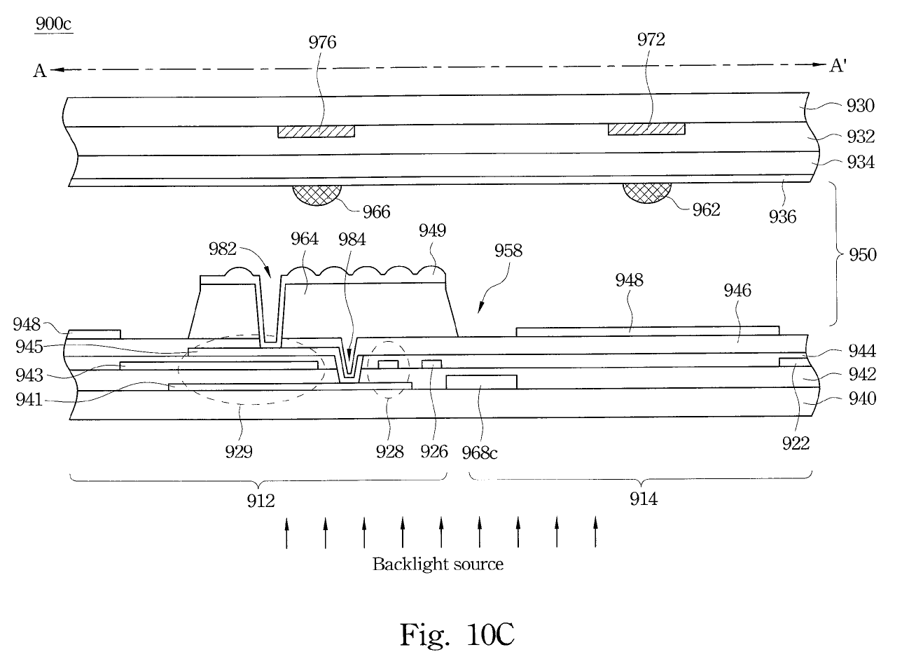

The reflective region 912 and the transparent region 914 are electrically coupled by connecting with the electrode 951. The main slit 958 is formed between the reflective region 912 and the transparent region 914. In the third embodiment, the shielding layer (e.g., the metal layer 968a in FIG. 10A, the metal layer 968b in FIG. 10B, the non-transparent insulating layer 968c in FIG. 10C, or a combination of the above) is formed at the main slit 958 for reducing the light leakage of the pixel structure 900 at dark state. In the following, the pixel structure 900a˜900c shown in FIGS. 10A˜10C are used to explain possible variations of the pixel structure 900 in FIG. 9.

FIG. 10A is a cross-sectional view of a first variation example of the pixel structure 900 in FIG. 9, where the pixel structure 900a is draw along the AA′ line of FIG. 9. The pixel structure 900a includes a pair of substrates 930, 940. A liquid crystal layer 950 with liquid crystal molecules is disposed between the substrates 930, 940. At least one of the substrates 930, 940 comprises a transparent material (e.g., glass, quartz, etc), a non-transparent material (e.g., silicon sheet, ceramics, etc), flexible material (e.g., polyester, polyethylene, polyamide, polyethanol, polycyclane, polyphenol, thinner glass, others, or combination of them), or a combination of them. The substrates 930, 940 in the third embodiment are glass substrates as an example.

The substrate 930 is disposed with a color filter 932 and an overcoat layer 934 covering the color filter 932. The common electrode 936 is formed on the overcoat layer 934. The material of the common electrode 936 is a transparent conductive material, such asindium tin oxide (ITO), aluminum zinc oxide (AZO), cadmium tin oxide (CTO), indium zinc oxide (IZO), aluminum tin oxide (ATO), hafnium oxide (HfO), or others, or any combination thereof. Alignment elements 962, 966 are disposed on he common electrode 936. Black matrices 972, 976 are disposed correspondingly on or substantially aligned with the alignment elements 962, 966.

A semiconductor layer 941, an insulating layer 942, a first metal layer (M1) 943, an insulating layer 944, a second metal layer (M2) 945, a passivation layer 946, and pixel electrodes 948, 949 are formed in sequence on the substrate 940. They are respectively patterned to form a thin-film transistor 928, a storage capacitor 929, a common line 922, a scan line 926, a contact hole 982, and a via hole 984.

At least one of the materials of the insulating layer 942, insulating layer 944, overcoat layer 934, and passivation layer 946 comprises an organic material [e.g., photo resist, polyarylene ether (PAE), polyester, polyethylene, polyamide, polyethanol, benzocyclclobutene (BCB), hydrogen silsesquioxane (HSQ), methyl silesquioxane (MSQ), SiOC—H, or some other material, or a combination of the above], an inorganic material (e.g., silicon oxides, silicon nitrides, silicon oxy-nitride, silicon carbonates, hafnium oxides, some other material, or a combination of the above), or any combinations thereof. The pixel electrode 948 in the transparent region 914 is made of a transparent conducting material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combinations thereof.

The semiconductor layer 941 comprises a polycrystal material containing Si, microcrystal material containing Si, single crystal material containing Si, amorphous material containing Si, or any combinations thereof. The patterned organic material layer 964 in the reflective region 912 is disposed on the passivation layer 946. It renders an optical path for the reflected light in reflective region 912 that is substantially equal to an optical path for transmitted light in the transparent region, in order to optimize the performance of transmissive optics and reflective optics. The pixel electrode 949 being a reflective material is disposed on the patterned organic material layer 964 adapted to reflect light of the environment in the reflective region 912. The pixel electrode 949 employs a rough and uneven surface of the patterned organic material layer 964, and is formed with a metal layer with high reflectivity (e.g., Al, Au, Ag, Cr, Mo, Nb, Ti, Ta, W, Nd, their alloys, some other material, or a combination of the above) on the rough and uneven surface of the patterned organic material layer 964 to form the rough and uneven surface of the pixel electrode, or a reflective metal layer formed with a rough and uneven surface on the surface without roughness and unevenness of patterned organic material layer 964, or combinations thereof.

The shielding layer can be a non-transparent metal layer, a non-transparent insulating layer, or combinations thereof. The first variation example of FIG. 10A employs the non-transparent metal layer 968a in the second metal layer 945 as the shielding layer of the pixel structure 900a. The metal layer 968a can be selectively connected with or non-connected with the data line 924, and the data line 924 is made from on the second metal layer 945, for example. That is, the metal layer 968a functioning as a shielding layer can be connected to a specific potential or be floating without connecting to any potential, such as the scan line, data line, common line, or other signal source line.

FIG. 10B is the cross-sectional view of the second variation of the pixel structure 900 in FIG. 9. The pixel structure 900b is drawn along the AA′ line in FIG. 9. The second variation in FIG. 10B employs the non-transparent metal layer 968b in the first metal layer 943 as the shielding layer of the pixel structure 900b. Moreover, the metal layer 968b is preferably floating instead of connecting to any particular potential. It can also be connected with the scan line 926 on the first metal layer 943 to have a specific potential, and the scan line 926 is made from the first metal layer 343, for example.

In FIG. 10C, the pixel structure 900c is drawn along the AA′ line in FIG. 9. The third variation example in FIG. 10C employs the non-transparent insulating layer 968c as the shielding layer of the pixel structure 900c. The material of the non-transparent insulating layer 968c is preferably a photo resist, some other organic material (in the color of, for example, black, light color, multiple colors covering each other, or some other color), an inorganic material, or any combinations thereof. It can be selectively formed on at least one of the substrate 940, the insulating layer 942, the insulating layer 944, and the passivation layer 946. For example, it can be disposed at the positions illustrated in FIGS. 10A˜10C or some other position. The shielding layer in the third embodiment can be implemented by selectively using at least two schemes in FIGS. 10A˜10C.

The first and third embodiments illustrated in FIGS. 4A to 4C and 10A to 10C show that the color filter layer and the thin-film transistor are disposed on different substrates. In the following paragraphs, fourth and fifth embodiments are used to show examples where the color filter layer and the thin-film transistor are on the same substrate.

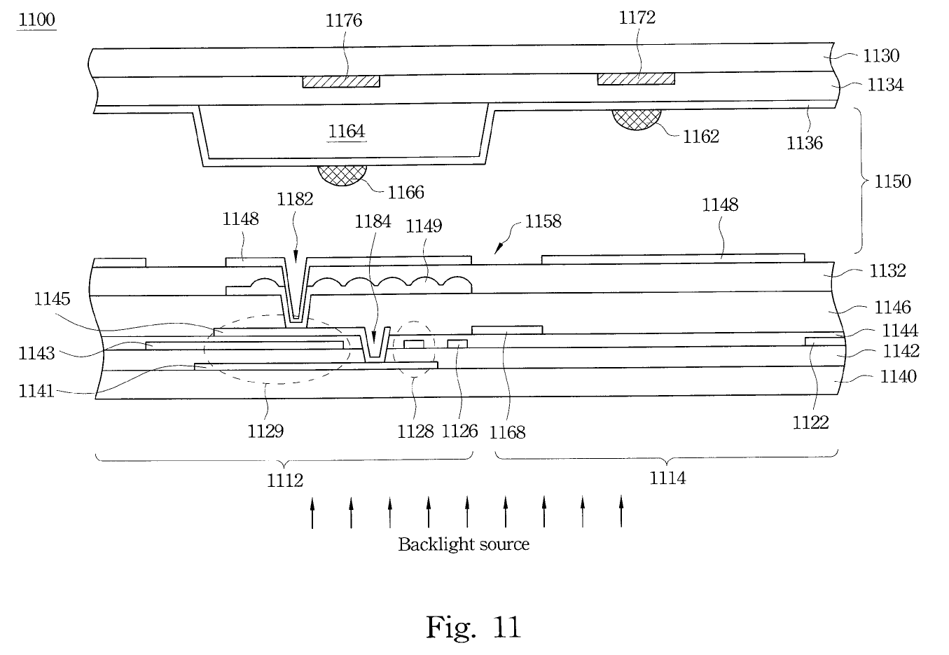

FIG. 11 is a cross-sectional view of the pixel structure in the fourth embodiment. In the following description, one sub-pixel region is the reflective region 1112, and the other is the transparent region 1114. This configuration merely serves as an example of the present invention. For example, the sub-pixel regions in a pixel region can be all transparent or reflective.

The pixel structure 1100 includes a pair of substrates 1130, 1140. A liquid crystal layer 1150 with a plurality of molecules is disposed between the substrates 1130, 1140. The material of at least one of the substrates 1130, 1140 comprises a transparent material (e.g., glass, quartz, etc), non-transparent material (e.g., silicon plate, ceramics, etc), flexible material (e.g., polyester, polyethylene, polyamide, polyethanol, polycyclane, polyphenol, thinner glass, others, or combination of them). The substrates 1130, 1140 in the fourth embodiment are glass substrate as an example.

The substrate 1130 is disposed with an overcoat layer 1134. The reflective region 1112 has a patterned organic material layer 1164 disposed on the overcoat layer 1134. The patterned organic material layer 1164 of the reflective region 312 renders an optical path for the reflected light in reflective region 1112 that is substantially equal to an optical path for transmitted light in the transparent region, in order to optimize the performance of transmissive optics and reflective optics. The common electrode 1136 covers the overcoat layer 1134 of the transmissive region 1114 and the patterned organic material layer 1164 of the reflective region 1112. The common electrode 1136 is made of a transparent conductive material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combinations thereof. Alignment elements 1162, 1166 are formed on the common electrode 1136. Black matrices 1172, 1176 are disposed on and aligned with the alignment elements 1162, 1166.

A semiconductor layer 1141, an insulating layer 1142, a first metal layer (M1) 1143, an insulating layer 1144, a second metal layer (M2) 1145, a passivation layer 1146, a reflective layer 1149, a color filter layer 1132, and a pixel electrode 1148 are formed in sequence on the substrate 1140. They are respectively patterned to form a thin-film transistor 1128, a storage capacitor 1129, a common line 1122, a scan line 1126, a contact hole 1182, and a via hole 1184.

At least one of the materials of the insulating layer 1142, insulating layer 1144, passivation layer 1146, and overcoat layer 1134 comprises an organic material [e.g., photo resist, polyarylene ether (PAE), polyester, polyethylene, polyamide, polyethanol, benzocyclclobutene (BCB), hydrogen silsesquioxane (HSQ), methyl silesquioxane (MSQ), SiOC—H, or some other material or a combination of the above], an inorganic material (e.g., silicon oxides, silicon nitrides, silicon oxy-nitride, silicon carbonates, hafnium oxides, some other material, or a combination of the above), or any combinations thereof. The pixel electrode 1148 is made of a transparent conducting material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combinations thereof.

The semiconductor layer 1141 comprises a polycrystal material containing Si, microcrystal material containing Si, single crystal material containing Si, amorphous material containing Si, or any combinations thereof. The reflective layer 1149 is made of a reflective material, disposed on the passivation layer 1146 corresponding to the patterned organic material layer 1164 adapted to reflect light of the environment in the reflective region 1112. The reflective layer 1149 employs a surface with rough and uneven of the passivation layer 1146, and then coating a metal layer with high reflectivity (e.g., Al, Au, Ag, Cr, Mo, Nb, Ti, Ta, W, Nd, their alloys, other material, or a combination of the above) on the surface with rough and uneven of the passivation layer 1146 to form the surface with rough and uneven of the reflective layer 1149, or a reflective metal layer rough and uneven surface formed on the surface without roughness and unevenness of the passivation layer 1146, or combinations thereof.

In the fourth embodiment shown in FIG. 11, the non-transparent metal layer 1168 in the second metal layer 1145 serves as the shielding layer of the pixel structure 1100. The metal layer 1168 is disposed corresponding to and aligned with the main slit 1158 of the pixel electrode 1148. It can be connected to a specific potential or be floating without connecting to any potential, such as the scan line, data line, common line, or other signal source line. According to a variation example of the fourth embodiment, the non-transparent metal layer in the first metal layer 1143 or an non-transparent insulating layer [preferably a photo resist material, an organic material (in the color of, for example, black, light color, multiple colors covered with each other, or some other color), an inorganic material, or any combinations thereof] can serve as the shielding layer. Black matrices can be selectively employed to reduce the light leakage of the pixel structure 1100 at the dark state. Of course, the configuration of the shielding layer and black matrices can be varied according to the above-mentioned examples.

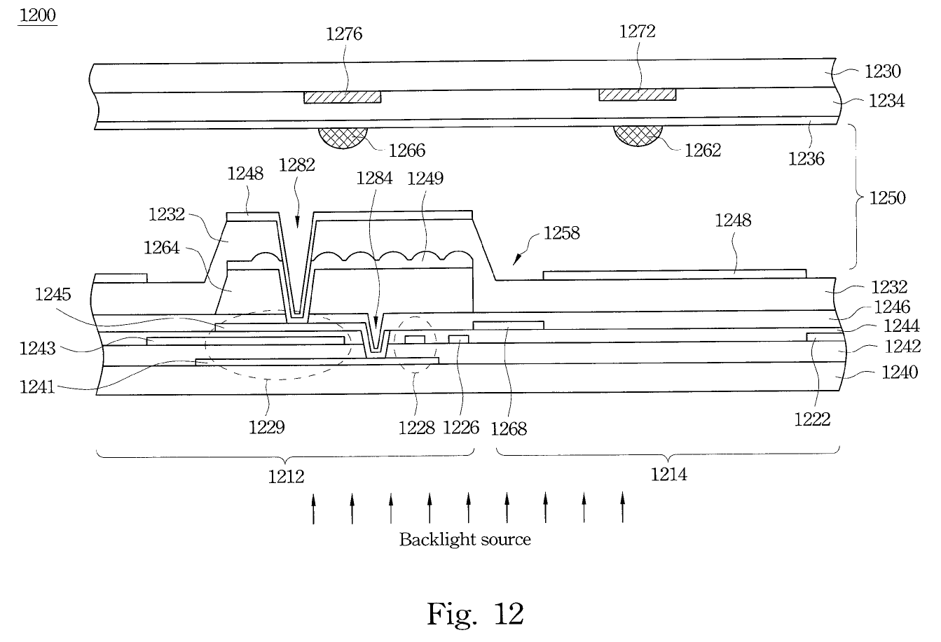

FIG. 12 is a cross-sectional view of the pixel structure in the fifth embodiment. In the following description, one sub-pixel region is the reflective region 1212, and the other is the transparent region 1214. This configuration merely serves as an example of the present invention. For example, the sub-pixel regions in a pixel region can be all transparent or reflective.

The pixel structure 1200 includes a pair of substrates 1230, 1240. A liquid crystal layer 1250 with a plurality of molecules is disposed between the substrates 1230, 1240. The material of at least one of the substrates 1230, 1240 comprises a transparent material (e.g., glass, quartz, etc), non-transparent material (e.g., silicon plate, ceramics, etc), flexible material (e.g., polyester, polyethylene, polyamide, polyethanol, polycyclane, polyphenol, thinner glass, others, or combination of them). The substrates 1230, 1240 in the fifth embodiment are glass substrate as an example.

The substrate 1230 is disposed with an overcoat layer 1234. A common electrode 1236 is formed on the overcoat layer 1234. The common electrode 1236 is made of a transparent conductive material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combinations thereof. The common electrode 1236 is provided with alignment elements 1262, 1266. Black matrices 1272, 1276 are disposed on and aligned with the alignment elements 1262, 1266.

A semiconductor layer 1241, an insulating layer 1242, a first metal layer (M1) 1243, an insulating layer 1244, a second metal layer (M2) 1245, an insulating layer 1246, a reflective layer 1249, a color filter layer 1232, and a pixel electrode 1248 are formed in sequence on the substrate 1240. They are respectively patterned to form a thin-film transistor 1228, a storage capacitor 1229, a common line 1222, a scan line 1226, a contact hole 1282, and a via hole 1284.

At least one of the materials of the insulating layer 1242, insulating layer 1244, insulating layer 1246, and overcoat layer 1234 comprises an organic material [e.g., photo resist, polyarylene ether (PAE), polyester, polyethylene, polyamide, polyethanol, benzocyclclobutene (BCB), hydrogen silsesquioxane (HSQ), methyl silesquioxane (MSQ), SiOC—H, or some other material or a combination of the above], an inorganic material (e.g., silicon oxides, silicon nitrides, silicon oxy-nitride, silicon carbonates, hafnium oxides, some other material, or a combination of the above), or any combinations thereof. The pixel electrode 1248 is made of a transparent conducting material, such as indium tin oxide (ITO), aluminum zinc oxide (AZO), cadmium tin oxide (CTO), indium zinc oxide (IZO), aluminum tin oxide (ATO), hafnium oxide (HfO), or others, or any combination thereof.

The semiconductor layer 1241 comprises a polycrystal material containing Si, microcrystal material containing Si, single crystal material containing Si, amorphous material containing Si, or any combinations thereof. The patterned organic material layer 1264 in the reflective region 1212 is disposed on the insulating layer 1246 so that it renders approximately the same optical path for the reflected and transmitted light in the reflective region 1212, optimizing the performance of transmissive and reflective optics. The patterned organic material layer 1264 is disposed with a reflective layer 1249 made of a reflective material adapted to reflect a light of an environment in the reflective region 1212. The reflective layer 1249 employs a rough and uneven surface of the patterned organic material layer 1264, and is formed with a metal layer with high reflectivity (e.g., Al, Au, Ag, Cr, Mo, Nb, Ti, Ta, W, Nd, their alloys, some other material, or a combination of the above) on the rough and uneven surface of the patterned organic material layer 1264 to form the surface with roughness and unevenness of the pixel electrode, or a reflective metal layer with a rough and uneven surface formed on the surface without roughness and unevenness of the patterned organic material layer 1264, or combinations thereof.

In the fifth embodiment shown in FIG. 12, the non-transparent metal layer 1268 is the second metal layer 1245 serves as the shielding layer of the pixel structure 1200. The metal layer 1268 is disposed corresponding to or substantially aligned with the main slit 1258 of the pixel electrode 1248. It can be connected to a specific potential or be floating without connecting to any potential, such as the scan line, data line, common line, or other signal source line. According to a variation of the fifth embodiment, the non-transparent metal layer is the first metal layer 1243 or an non-transparent insulating layer [preferably a photo resist material, an organic material (in the color of, for example, black, light color, multiple colors covering each other, or some other color), an inorganic material, or a combination of the above] can serve as the shielding layer. Black matrices can be selectively employed to reduce the light leakage of the pixel structure 1200 at dark state. Of course, the configuration of the shielding layer and black matrices can be varied according to the above-mentioned examples.

The embodiments in FIGS. 11 and 12 explain the pixel structure with the color filter on array (COA). Any person skilled in the art can apply the same idea to the pixel structure with the array on color filter (AOC). Moreover, the patterned organic material layer can be selectively disposed on one of the two substrates.

The present invention does not limit possible forms of the alignment elements and thin-film transistors in the pixel structure. The alignment element can be a round protrusion, taper protrusion, alignment groove, alignment slit, some other type of alignment element, or their combinations. Moreover, the number of alignment elements in a sub-pixel region can be one or more. They can be selectively disposed on one of the two substrates or simultaneously on both substrates. Besides, the thin-film transistors in the above-mentioned embodiments are of the top-gate type. However, they can be replaced by the bottom-gate type of thin-film transistors as well.

A sixth embodiment of the present invention provides a display panel and the method for manufacturing thereof. This display panel includes the above-mentioned pixel structure and the method for manufacturing the same.

A seventh embodiment of the present invention provides an electro-optical device and the method for manufacturing the same. This electro-optical device includes the above-mentioned display panel and the method for manufacturing the same.

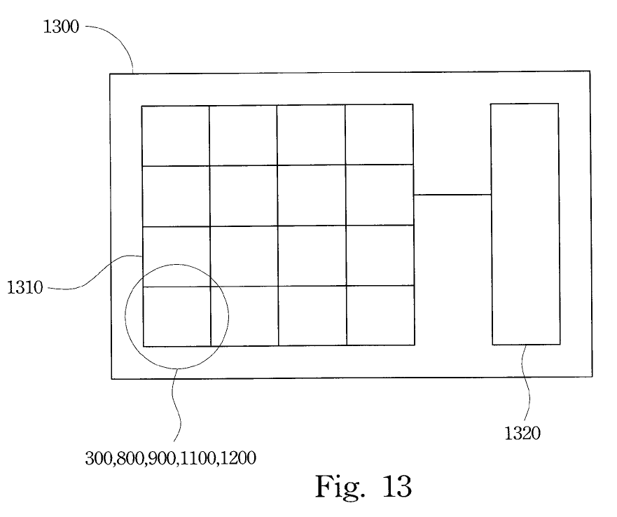

FIG. 13 is a schematic view of an electro-optical device according to the seventh embodiment of the invention. The electro-optical device 1300 uses the display panel 1310 having the pixel structure (e.g., 300, 800, 900, 1100, or 1200) in the first to fifth embodiments. The electro-optical device 1300 further has an electronic element 1320, such as a control element, operating element, processing element, input element, memory element, driving element, light emitting element, protecting element, sensing element, detecting element, element of other functions, or combination of the above) connecting with the display panel 1310. The types of the electro-optical device 1300 include portable products (e.g., cell phones, video cameras, cameras, laptop computers, game boys, watches, music players, electronic photos, electronic mailbox, navigators, etc), audio-video (AV) products (e.g. AV players, etc), screens, televisions, indoor or outdoor display boards, panels inside the projectors, etc.

The present invention being thus described, it will be obvious that the same may be varied in many ways. Such variations are not to be regarded as a departure from the spirit and scope of the present invention, and all such modifications as would be obvious to one skilled in the art are intended to be included within the scope of the following claims.

While the present invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A pixel structure, comprising:
a pair of substrates;
a liquid crystal layer disposed between the substrates;
a plurality of pixel regions provided on the substrates, each of which is defined by at least two common lines and at least one data line, and each of the pixel regions has at least two sub-pixel regions and a pixel electrode with at least one main slit, the main slit being adjacent to the border of the sub-pixel regions;
a patterned organic material layer, disposed on one of the substrates, and substantially aligned with one of the sub-pixel regions; and
a shielding layer substantially aligned with the main slit.

2. The pixel structure of claim 1, wherein the sub-pixel region includes a reflective region, a transparent region, or combinations thereof.

3. The pixel structure of claim 1, wherein the shielding layer includes a non-transparent metal layer connected to the data line.

4. The pixel structure of claim 1, wherein the shielding layer includes a non-transparent metal layer not connected to the data line.

5. The pixel structure of claim 1, wherein the shielding layer includes a non-transparent insulating layer.

6. The pixel structure of claim 3, wherein the shielding layer includes a non-transparent insulating layer.

7. The pixel structure of claim 4, wherein the shielding layer includes a non-transparent insulating layer.

8. The pixel structure of claim 1, further comprising a color filter disposed on one of the substrates.

9. The pixel structure of claim 1, further comprising a gate line and a thin-film transistor disposed under the sub-pixel region substantially aligning with to the patterned organic material layer.

10. The pixel structure of claim 1, further comprising an alignment element disposed in the sub-pixel regions.

11. A display panel incorporating the pixel structure of claim 1.

12. An electro-optical device incorporating the display panel of claim 11.

13. A method for manufacturing a pixel structure, the method comprising:
providing a pair of substrates;
forming a plurality of pixel regions on the substrates, each of which is defined by at least two common lines and at least one data line, and each of the pixel regions has at least two sub-pixel regions;
forming a pixel electrode with at least one main slit at the border of the two sub-pixel regions in each of the pixel regions;
disposing a patterned organic material layer on one of the substrates, substantially aligning with one of the sub-pixel regions; and
forming a shielding layer substantially aligning with to the main slit.

14. The method of claim 13, wherein the sub-pixel region includes a reflective region, a transparent region, or combinations thereof.

15. The method of claim 13, wherein the shielding layer includes a non-transparent metal layer connected to the data line.

16. The method of claim 13, wherein the shielding layer includes a non-transparent metal layer not connected to the data line.

17. The method of claim 13, wherein the shielding layer includes a non-transparent insulating layer.

18. The method of claim 15, wherein the shielding layer includes a non-transparent insulating layer.

19. The method of claim 16, wherein the shielding layer includes a non-transparent insulating layer.

20. The method of claim 13, further comprising forming a color filter on one of the substrates.

21. The method of claim 13, further comprising forming at least a gate line and a thin-film transistor under the sub-pixel region substantially aligning with the patterned organic material layer.

22. The method of claim 13, further comprising forming an alignment element in the sub-pixel region.

23. The method for manufacturing a display panel incorporating the method for manufacturing the pixel structure of claim 13.

24. The method for manufacturing an electro-optical device incorporating the method for manufacturing the display panel of claim 22.
